(19) United States
(12) Patent Application Publication
(10) Pub. No.: US 2005/0249008 A1
(43) Pub. Date: Nov. 10, 2005

(54) SILICON STORAGE MEDIA, AND CONTROLLER THEREOF, CONTROLLING METHOD THEREOF, AND DATA FRAME BASED STORAGE MEDIA

(76) Inventor: Hsiang-An Hsieh, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/904,824

(22) Filed: Dec. 1, 2004

(30) Foreign Application Priority Data
May 6, 2004 (TW) 93112722

(51) Int. Cl. G11C 7/02

(52) U.S. Cl. 365/210

(57) ABSTRACT

The present invention provides a silicon storage media controller to utility silicon storage media in accordance with a translation table and an address mapping module that comprise the information of preceding description bits of a data frame. When the process of reading and writing data is initially executing, the silicon storage media controller receives a data frame and refers the translation table and the address mapping module to increase the speed of data reading and updating, so that a translation table buffer and an address mapping module are provided for the controller. Additionally, those including memory block status, start address, data length, compression algorithm indicator, and parameter indicator are comprised in the preceding description unit that lead the data frame so as to establish translation table.

### CROSS-REFERENCE TO RELATED APPLICATION

This application claims the priority benefit of Taiwan application serial no. 93112722, filed May 6, 2004.

### BACKGROUND OF THE INVENTION

1. Field of the Invention

The present invention relates to a silicon storage media controller, and more particularly, to a silicon storage media controller with variable length data frame.

2. Description of Related Art

Presently, it is common to use a memory made of silicon chip as silicon storage media. Most of the silicon storage media are connected to a system interface via a controller in order to write information into memory or read information from memory and transmit information to the system. Wherein, since it is characterized by its low power consumption, high reliability, high capacity, fast access speed, the silicon storage media had been widely applied in various portable digital electronic apparatus, such as the products of digital camera, digital walkman, personal digital assistant (PDA), and its business market grows rapidly now. Many types of the silicon storage media are derived from the original silicon storage media, they are: Compact Flash Card (CF), Memory Stick Card (MS), Secure Digital Card (SD), Smart Media Card (SM), etc. In addition, in the personal computer application field, the USB portable disk installed via the Universal Serial Bus (USB) has become a very popular new product recently.

The storage capacity of various portable storage apparatus used as the silicon storage media and made of the silicon chip memory mentioned above are limited by the capacity of its embedded memory. The controller inside the portable storage apparatus only has one interface connected to a system to receive instruction and accessing memory content accordingly. Therefore, in order to reduce cost, the major subject is to fully utilize the limited capacity of the memory, since the memory chip is the most cost to a portable storage apparatus.

The conventional silicon storage media controller records the original data into the memory directly in accordance with the mapping method that a page as the minimum memory unit performing the read/write operation, and a redundant area in the page is used to record the information of the logic address mapping code and the correction code. In general, a single sector size is 528 bytes as the most popular capacity unit used by the storage apparatus, whose size is also equal to the capacity of a unit sector. A new type of memory with up to 2048 bytes of the single page memory capacity and 64 bytes of the redundant area capacity is further provided in the prior art. However, the controller still uses the same technique to control it. In order words, the data compression/decompression function is not introduced to the logic address mapping code, which is recorded and corresponded to a single page.

Referring to FIG. 1A, a block diagram of the internal structure of a conventional silicon storage media is shown. The silicon storage media 100 comprises a controller 110 and one or more memories 120. The controller 110 comprises a microprocessor 114, and the microprocessor 114 communicates and transmits instruction and data to a system via a system interface 112, wherein the silicon storage media is accessed by the system. After data is temporarily stored in a data buffer 116, the data is either written into the memory 120 via a memory interface 118 or read from the memory 120 and temporarily stored into a data buffer 116. Afterwards, the data is sent back to the system that requests to read the data via the system interface 112.

During the process to record the original data transmitted from the system into the memory, the process also records related controlling information such as the status flag, error correction code, logic address, and other non-used reserved space those belong to some of the data of data memory block. Each bit in the controlling related information is defined hereinafter, wherein: Status flag: indicates the status of the data stored in a memory block with “erased”, “in-used”, or “bad”. If it is “erased”, the memory block can be used to record an updated data and the flag is then changed to “in-used”. If it is found during the writing operation that the memory for recording the data is defective and cannot be used any more to store data properly, the block is then marked as “bad”. After the data stored in the memory block with “in-used” mark is updated and moved to the other “erased” block, the memory block is then recovered to the “erased” status by the erasing operation. Error correction code: several bytes of the error correction code are generated from the original data by using a specific algorithm. If the error correction code is detect, then the procedure of correction will take place to correct the error, and a correct data is then sent back to the system. When the microprocessor detects an error occurred in the memory unit where the original data is recorded, the correct data is moved and copied to another “erased” data block immediately, and the defect data block is marked as “bad”. Logic address: a translation table to mirror the origin data is produced in accordance with the process of scheming the memory configuration. When storing the original data into the memory, the microprocessor has to properly plan, dispose and utilize the memory adapting to the physical addressing method suitable for the memory. Therefore, there is a great difference existed between the disposition sequence it uses and the logic address sequence adopted by the system to access the memory. Accordingly, it is required to install an address converting circuitry or an address converting control process in the controller The translation table is used to convert the logic address provided by the system to/from the physical address in the memory. In order to maintain such translation relationship even after the power shut down system, it is required to preserve both the original data and its corresponding logic address simultaneously.

As mentioned above, a commonly used NAND flash memory is exemplified herein to describe a data block record format in the memory as shown in FIG. 1B. An NAND flash memory with a 528 bytes as storage unit is an example below. Among the storage unit of 528 bytes, 512 bytes are used as a storage space to record the original data, and the rest of 16 bytes (also known as a control information record area) are used to recording the control information mentioned above. After the required control information is stored, it is common that the control information record area still have some space left.

Referring to FIG. 2, a configuration of a silicon storage media and a controller thereof provided by the prior art are shown. Wherein, a silicon storage media 200 with data compression function comprises a controller 210 and at least one memory 220. The controller 210 comprises a system interface 211 serving as a data exchange channel between the system and the silicon storage media controller; a microprocessor 212 for performing reading, writing and erasing operations; and a memory interface 216 serving as a data exchange channel between the memory 220 and the silicon storage media controller 210. In addition, in order to implement the data compression function, the controller 210 further comprises a data compression/decompression module 214. In order to accelerate the data access between the system and the memory 220, the controller 210 further comprises a first system data buffer 213a and a second system data buffer 213b for temporarily storing the data exchanged with the system, and a first memory data buffer 215a and a second memory data buffer 216b for temporarily storing the data exchanged with the memory. Alternatively, it is also possible that only the single system data buffer 213a and the memory data buffer 215a are used as the buffer for temporarily storing the data, and its physical implementation is depended on design consideration.

In summary, in the conventional silicon storage media controller configuration and the conventional data record structure, the original data is directly stored into a planned location in the memory without being compressed. As a result, the storage capacity of this type of silicon storage media can be improved only by adding new memory hardware and the compression method does not help in increasing the storage capacity of this type of memory card. In addition, the conventional silicon storage media uses “page” as a unit to read or write, so that the compression mechanism could not improve the performance of data process, since the unit is too small. Moreover, although the control information related to the translation indicator and the error-detection correction code are marked in the reserved redundant area in each page, there is still some space available. Furthermore, its translation table is generated by mapping the fixed original data length to the memory page. In other words, all operations including reading, writing, updating data and updating translation table are operated based on the fixed original data length. However, this type of fixed length storage structure cannot use its existing translation table to perform the data read/write translation in the silicon storage media with compression mechanism.

### SUMMARY OF THE INVENTION

Therefore, the present invention is designated to provide a silicon storage media with a larger access unit, for example, a memory block, as the data record format and mapping mode for a data frame. Besides, there is one translation table buffer configured by the controller to record a translation table for further access operations.

The present invention is designated to configure a silicon storage media and its controller with a configuration, a controlling method, a data record format, and a mapping mode thereof. Wherein, when the controller is updating the data frame, the translation table recorded in the translation table buffer is also updated simultaneously, and the relationship of translation is marked in a preceding description unit leading to the updated data frame.

The present invention is also designated to accelerate the searching of the data translation code in the translation table buffer according to the read/write access instruction provided by the system for a corresponding memory block address, so as to rapidly read the data frame and send the data back to the system or update the data. Besides, there is an address mapping module added into the controller.

In order to increase the storage capacity of the storage media, there is a data compression/decompression unit further added into the silicon storage media controller, and the data is compressed before it is stored and decompressed after it is read out from the storage media. Therefore, in the present invention, first, the space occupied by the original data can be decreased by way of data compression. Before the data is recorded into the planned location in the memory, the “preceding description unit” is added in front of the data which has been compressed by the controller, and a “posterior data error checking code” is added behind its tail so as to form a “data frame” that is nearby the storage capacity of a “memory block”. Secondly, the translation indicator and the error-detection correction code are both marked in the “preceding description unit” of the “data frame” stored in the “memory block”. Therefore, the storage space of each page occupied by the information is further reduced, and the effective space of the storage capacity in the silicon storage media, which can be physically used by the valid information in the system, can be improved accordingly. Finally, the translation table is established according to the basis of the “data frame” which is constituted of the original data length variable correspondingly. Then, all operations of reading, writing, updating data and updating translation table are operated in the basis of the “data frame” which correspond to the variable original data length.

In the present invention, the data frame can be stored at any location of the memory. The controller rebuilds the translation relation of the data frame and the original data according to the preceding description unit when it is initialized and starts to perform the scanning. The “translation table” is generated by the controller when it is initialized to start to scan the data frames stored in all memory blocks of the memory. After the translation table is generated, the translation table is continuously updated when the system is writing or updating data, so that the accuracy of the translation relationship is maintained. The “translation table” is constituted by a plurality of “mapping entries”, and each mapping entry records a status of a set of memory block in the memory. Depending on the size of the built-in translation table buffer, and the amount of the memory blocks included in the adaptive memory, the controller can either generate a completed translation table at one time, or generate a partial translation table based on the interval which is currently accessed by the system, or generate two or more sets of partial translation table by dividing it to a couple of specific ranges to improve the efficiency of accessing the buffer.

The content inside the mapping entry is marked according to the corresponding memory block status or the information indicated by the stored data frame.

After the controller is initialized, both of the block status marked in each memory block of the memory and the preceding description unit of the data frame are read first, and the read information is then recorded in the mapping entry, wherein the mapping entry is in the translation table and mapped to the memory block. The translation table may be implemented by a bidirectional series link, so as to allow the controller link the system address corresponded to the data frame and the position of the recorded memory block in a downward or upward sequence.

After the translation table is established, the controller is going to take the access instruction from the system. After the system issues a read instruction, the controller immediately performs a search in the translation table to derive the address of the memory block and the data frame corresponding to the system read access obtained from the translation table. If the mated data frame address is obtained, the data frame will be read into the data buffer, and the original data will be sent back to the system after it is decompressed. If the mated data frame address is not obtained, a record with a predetermined format will be sent back to the system directly.

On the other hand, after the system issues a read instruction, the controller immediately performs a search operation in the translation table in order to check and determine whether the address of the memory block corresponding to the system read access and the data frame address can be obtained from the translation table or not. If the corresponding data frame address is obtained, the data frame is read into the data buffer and decompressed. Then, the data frame is updated by the update data transmitted from the system, and the data frame, which is not recorded and updated by the memory block, is obtained. The memory block for recording the non-updated data frame is then erased. When the operations mentioned above are being performed, the translation table is synchronously updated. If the corresponding data frame address is not obtained, the data written from the system is used to generate the data frame directly, and the new built data frame recorded by the non-used memory block is obtained. When the operations mentioned above are being performed, the translation table is synchronously updated.

In summary, by integrating the compressing original data and the decompressing data frame which is recorded in the memory into the data frame based silicon storage media, and in accordance with the translation method described in the present invention, a translation table can be generated when the silicon storage media is initialized, and the translation table is updated when it is accessed. Even the conventional silicon storage media controller has a mechanism similar to this, the original data is directly recorded and stored in the prior art, and the way to handle the situation after the data is compressed is not disclosed in the prior art yet. Therefore, for the widely used silicon storage media application, the high speed non-volatile memory always takes a major portion of the total product cost. If the compression/decompression method can be integrated into the present invention and applied on the silicon storage media, it is possible to achieve the object of providing higher physical record capacity for the lower size memory, so as to further reduce product cost and improve product value.

Furthermore, the process of the present invention may be implemented via a firmware of the controller. In order to accelerate the data access in the system, some functions can be built into the address mapping module with the hardware circuitry, such that the controller can rapidly search and determine the status of the destination address accessed by the system mapping to the translation table for performing further operations.

### BRIEF DESCRIPTION OF THE DRAWINGS

The accompanying drawings are included to provide a further understanding of the invention, and are incorporated in and constitute a part of this specification. The drawings illustrate embodiments of the invention, and together with the description, serve to explain the principles of the invention.

FIG. 1A is a schematic diagram of a conventional silicon storage media and its internal configuration.

FIG. 1B is a schematic diagram illustrating a data block record format in a memory made of an NAND type flash memory.

FIG. 2 is a schematic diagram of a conventional silicon storage media with data compression function.

FIG. 3 is a schematic diagram of a translated data frame based silicon storage media and a controller thereof according to an embodiment of the present invention.

FIG. 4A is a schematic diagram illustrating a data frame format and its preceding description unit according to an embodiment of the present invention.

FIG. 4B is a schematic diagram illustrating a translation relation after the silicon storage media is initialized according to an embodiment of the present invention.

FIG. 5 is a flow chart illustrating a process for generating a translation table after the translated data frame based silicon storage media is initialized according to an embodiment of the present invention.

FIG. 6 is a flow chart illustrating a method for updating a non-used block series link table when the memory block is not used according to an embodiment of the present invention.

FIG. 7 is a flow chart illustrating a method for operating a new in-used block series link table when the memory block is in-used according to an embodiment of the present invention.

FIG. 8 is a flow chart illustrating a process for system to read data according to an embodiment of the present invention.

FIG. 9 is a flow chart illustrating a process for system to write data according to an embodiment of the present invention.

FIG. 10 is a flow chart illustrating a process for system to write data under a specific condition according to an embodiment of the present invention.

FIG. 11 is a flow chart illustrating a process for system to write data under another specific condition according to an embodiment of the present invention.

FIG. 12 is a flow chart illustrating a process for system to write data under yet another specific condition according to an embodiment of the present invention.

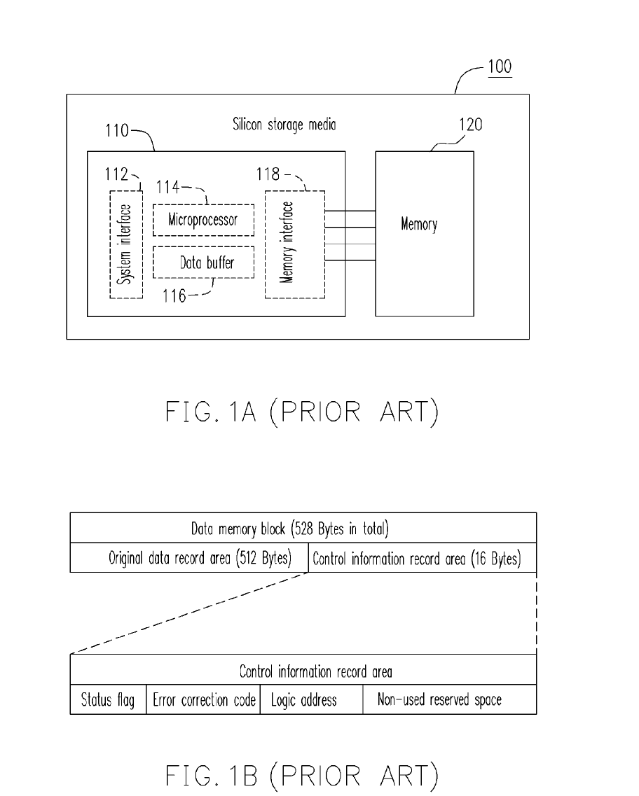

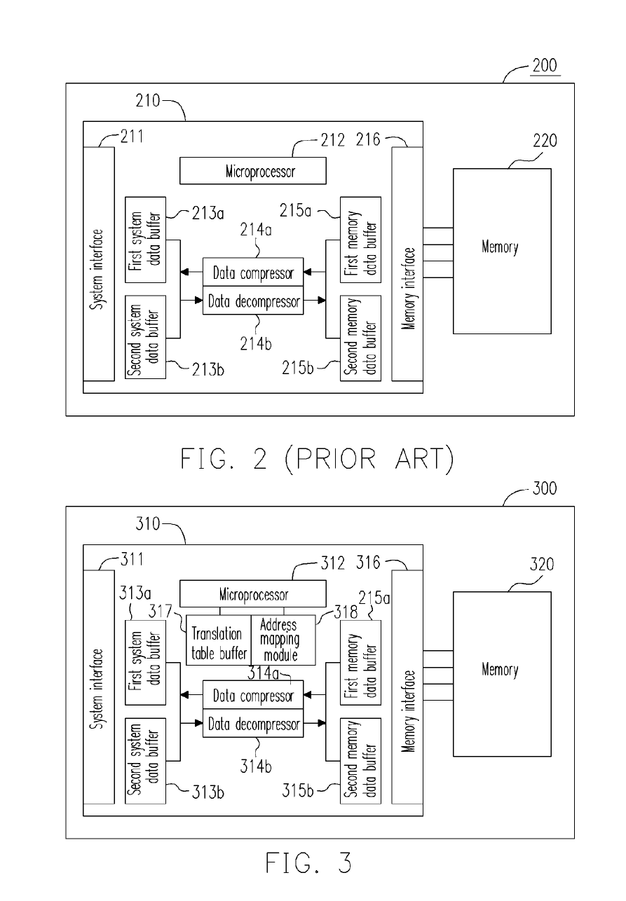

### DESCRIPTION OF THE PREFERRED EMBODIMENTS

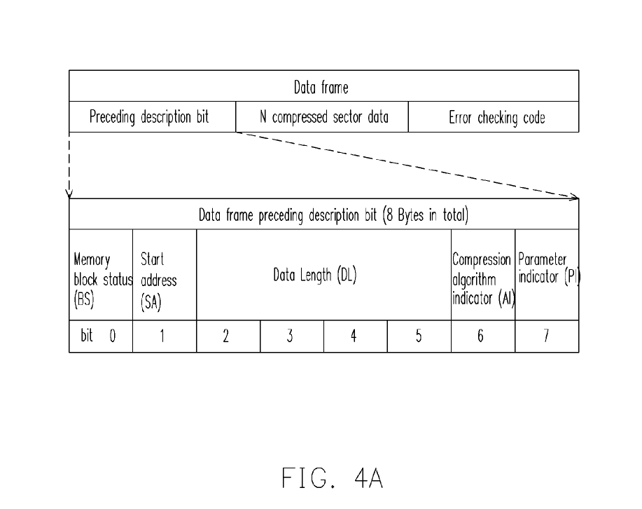

Referring to FIG. 3, according to an embodiment of the present invention, in order to support the silicon storage media with compression configuration mentioned above, a translation table buffer 317 is built in the controller 310. Wherein, a translation table for recording an address translation relationship between the fixed data length (transmitted from the system) and the variable data length (generated by the compression mechanism) is stored in the translation table buffer 317 (the way for generating the translation table is described hereinafter) for accessing data. In addition, in order to accelerate data searching, an address mapping module 318 is further added into the controller 310. The address mapping module 318 is used as a base of the access instruction provided by the system for obtaining a memory block address of the corresponding memory 220, and for reading the data frame in order to perform the update operation or send the data back to the system.

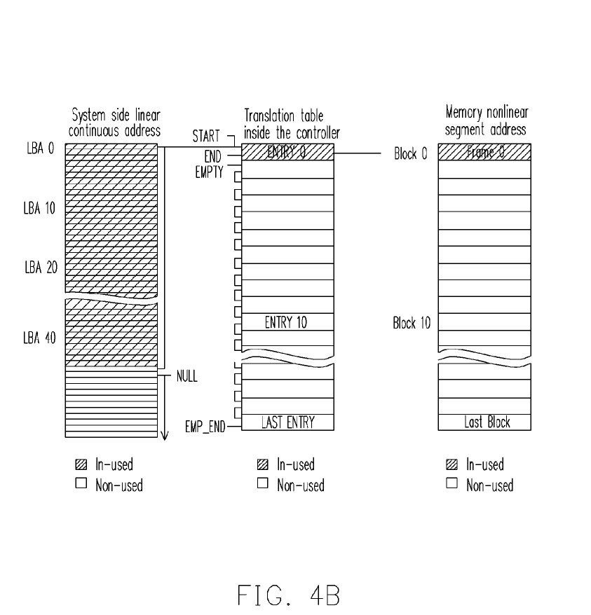

The silicon storage media 310 comprises a memory 320, and the memory 320 is constituted by a plurality of memory blocks. Wherein, each of the memory blocks is based on a specific data frame format. The data type included in each data frame is a variable data length, which is converted by the fixed data length transmitted by the system and compressed by a data compressor 314a. In order to manage the compressed data, a set of preceding description units is placed before the head of the data frame, and an error checking code is placed behind the tail of the data frame (referring to FIG. 4). With such design, placement of the control information in each page is not required, thus the utilization of the non-used space is improved. In addition, a plurality of compressed compressed sector data is recorded in between the preceding description unit and the error checking code.

Wherein, an original data start address and a data length corresponding to the compressed data are indicated in the “preceding description unit”, and the preceding description unit leads the data frame is shown in table 1.

TABLE 1
Format of the preceding description unit leads the data frame

| Address | Length | Name | Definition |
|---|---|---|---|
| 0 | 1 | BS | Block Status (Memory block status) |
| | | | FF: indicate the memory block is “erased” |
| | | | F0: indicate the memory block is “in-used” |
| | | | 00: indicate the memory block is “bad” |
| 1 | 4 | SA | Start Address (start address of the data |
| | | | packet corresponded to the original data) |
| 5 | 1 | DL | Data Length (original data length) |
| | | | (A sector is used as an unit of a capacity of |
| | | | 512 bytes) |
| 6 | 1 | AI | Algorithm Indicator |
| 7 | 1 | PI | Parameter Indicator |

It should be noted that the algorithm indicator and the parameter indicator are required to be added into the preceding description unit only if the compression/decompression function is required in the silicon storage media of the present invention. In addition, the format of the preceding description unit is not necessarily limited by the one shown in table 1, as long the data attribute and the data length recorded by each bit can successfully map the original data, they are within the scope of the present invention.

The translation table mentioned above is generated by reading the preceding description unit leads the data frame, and the translation table is constituted by a plurality of mapping entries (referring to FIG. 4B). Wherein, the translation table is used to determine the capacity and storage location of the original data corresponding to the data frame, and is used as an address translation mode for the linear continuous address in the system and the nonlinear segment address of the memory in the silicon storage media side.

In an embodiment of the present invention, referring to the preceding description unit stored in the memory block corresponding to the translation units, the format it constitutes and the meaning are shown in the following table.

TABLE 2

| Address | | | |
|---|---|---|---|
| (Bit) | Name | Length | Description |
| 0˜7 | BS | 4 | Block Status-Memory block status |
| | | | F: indicate the memory block is “erased” |
| | | | C: indicate the memory block is “in-used” |
| | | | 3: indicate the memory block is “bad” |
| 8˜31 | SA | 28 | Start Address- LBA start address |
| | | | corresponded to the data frame |
| 32˜39 | FL | 8 | Frame Length- Original data length |
| | | | included in the data frame, a sector is |
| | | | used as an unit herein |
| 40˜51 | PE | 12 | Previous Entry- Mapping to a |
| | | | translation unit of a previous data frame; |
| | | | FFF is a predetermined value, which |
| | | | indicates a start data frame |
| 52˜63 | NE | 12 | Next Entry- Mapping to a translation |
| | | | unit of a next data frame; |
| | | | FFF is a predetermined value, which |
| | | | indicates a final data frame |

Wherein, depending on the capacity of the translation table buffer 317 built in the controller 310 and the amount of the memory blocks included in the adaptive memory 320, the controller 310 can either generate a completed translation table at one time, or generate a partial translation table based on the interval currently accessed by the system, or generate two or more than two sets of partial translation table by dividing it to a couple of specific ranges.

A specific silicon storage media is described in detail hereinafter, wherein the memory only stores the basic data which is loaded after the system is initialized. A conventional FAT12 file system is exemplified herein for explanation, wherein the original data recorded in the silicon storage media at least comprises a master boot record, a partition table, a partition boot sector, a root directory and a file allocation table. For example, the silicon storage media is a 16 MB (Mbytes) memory, each page is 528 B (Bytes), and each memory block is 16 KB (Kbytes) equaling to 32 pages. By using a system linear continuous addressing method, the original data mentioned above occupies 48 sectors of address 0˜47, which equals to a 24 KB space. Its distribution is shown in table 3.

TABLE 3

| Original data | | |
|---|---|---|
| address | Data length | Data attribute |
| 0 | 1 | MBR—Master boot record, |
| | | partition table |
| 1˜26 | 26 | Non-used |
| 27 | 1 | BPB—Partition boot sector |
| 28˜29 | 2 | FAT—File allocation table |
| 30˜31 | 2 | FAT—File allocation table (copy) |
| 32˜47 | 16 | Root Directory |

After the information mentioned above have been compressed, no information is recorded in the original data address 1˜26, and an initial value 0×FF is set to all of its contents, such that a high compression ratio can be achieved. The rest of the information only occupies 22 sectors equaling to 11 KB of the original data. As a result, it is known that a data frame with a capacity less than 16 KB can be easily obtained by compression the initialized original data mentioned above.

Meanwhile, only one data frame is required to store the basic information which is loaded after the system is initialized. Wherein, the corresponding original start address is 0, and data length is 48. In addition, the preceding description unit status of the data frame is shown in table 4. Wherein, Al, Pl are depended on the most adaptive compression method selected by the controller based on the original data characteristic, and it is represented as 0×mm and 0×nn.

TABLE 4

| BS | SA | | | | DL | AI | PI |
|---|---|---|---|---|---|---|---|
| 0xF0 | 0x00 | 0x00 | 0x00 | 0x00 | 0x30 | 0xmm | 0xnn |

Referring to FIG. 4B, when the controller 310 is scanning the preceding description unit shown in table 3 mentioned above, since the silicon storage media is in the initialization state, the first memory block whose address is 0 is used to record the data frame, and the relationship between the linear continuous original data and the data frame is shown in FIG. 4B.

The “system linear continuous address” indicates after the silicon storage media is initialized in a way mentioned above, only 48 sectors (from LAB=0 to LBA=47) have meaningful information recorded in it, wherein the in-used block is represented by a filled dark color in the diagram. The “memory side nonlinear segment address” in FIG. 4B indicates an internal part of the memory, where the compressed data is stored in a way of using a memory block as a unit to store the data frame. In addition, the “translation table inside the controller” of FIG. 4B indicates an internal part of the controller, wherein the translation table is generated in order to link the system linear continuous address to the memory side segment address after the silicon storage media is initialized. Since it is the first in-used memory block, a translation unit is correspondingly generated in the translation table, and the information recorded in it is shown in table 5:

TABLE 5

| Address | | | |
|---|---|---|---|
| (Bit) | Name | Length | Description |
| 0˜7 | BS | 4 | C: in-used |
| 8˜31 | SA | 28 | Start Address = 0x00 |
| 32˜39 | FL | 8 | Frame Length = 0x30 |
| 40˜51 | PE | 12 | Previous Entry = FFF |
| 52˜63 | NE | 12 | Next Entry = FFF |

The step of generating the translation table is described in detail hereinafter.

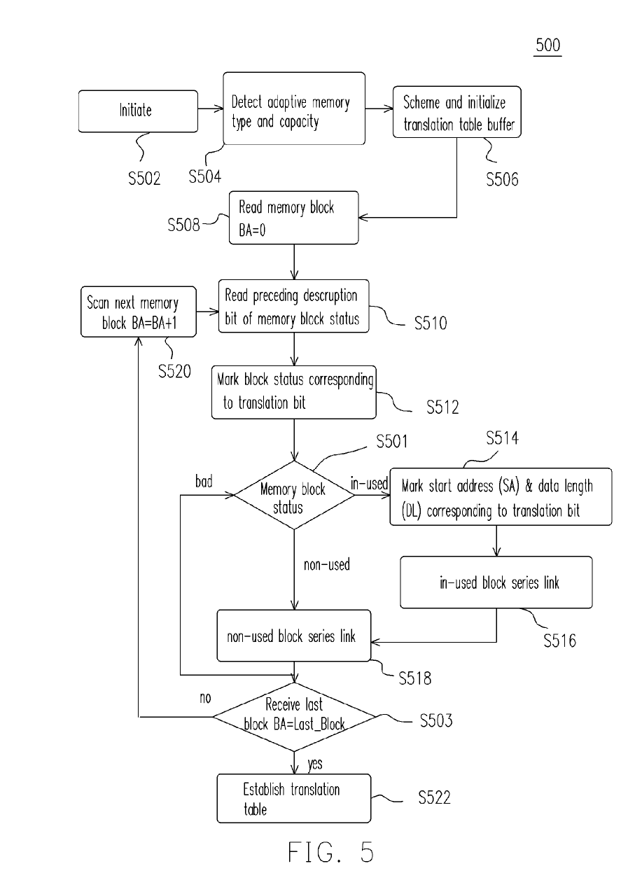

Referring to FIG. 5, a flow chart illustrating a process of generating the translation table after the controller is initialized (s502) is shown. First, the type and capacity of an adaptive memory is detected (s504), wherein a last block is defined as “last_block” first, then the translation table buffer is schemed and initialized (s506), and the memory block BA=0 is read (s508). Then, the preceding description unit of each memory block is read (s510), and the marked block status it reads is recorded in the translation units (s512). Meanwhile, it is determined whether the memory block is in-used or not (s501). If it is determined that the block is in-used, the start address (SA) and the data length (DL) of the translation units are marked (s514), the in-used block series link in the translation table is updated (s516), and the non-used block series link in the translation table is updated (s518). If it is determined that the block is non-used, the non-used block series link in the translation table is updated directly (s518). Meanwhile, if it is found that some block is bad, the process returns to the step of determining the memory block status (s501). If there is no bad block, it is then determined whether the last block matches BA=last_block or not (s503). If it is, the generation of the translation table is totally completed (s522). Otherwise, the next memory block BA=BA+1 is scanned, and the preceding description unit of the memory block is continuously read in (s510).

Since a non-used block series link table and an in-used block series link table are used in generating the translation table, a data structure of a bi-directional series link is used in a preferred embodiment of the present invention, such that the controller can link the corresponding system address and the recorded memory block position start from the start address in a downward or upward sequence.

The process of generating these two series link tables is described in detail hereinafter.

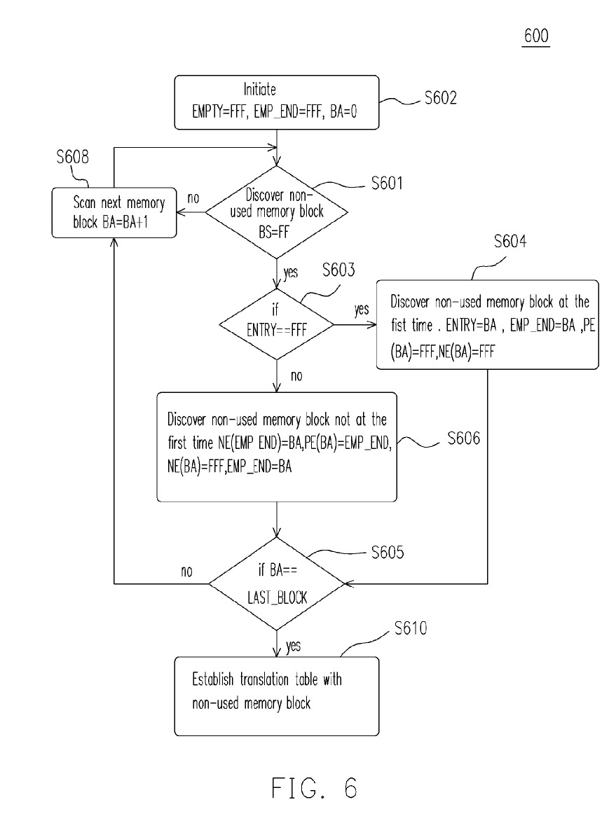

Referring to both FIGS. 4B and 6, which schematically show a process of updating the non-used series link table when the memory block is not used yet. Two indicators EMPTY and EMP_END shown in FIG. 4B are used as the reference indicators for generating the non-used block series link table. First, two indicators are initialized to a default value (e.g. FFF), and the block address (BA) of the memory is set to 0 (s602). If it is found at step s601 that there is a non-used memory block (BS=FF), it is then determined whether the indicator EMPTY is a default value or not (i.e., the entry is FFF or not as shown in step s 603). If it is, which means it is a first found non-used memory block, in such case, two indicators are set to the address of the current non-used bock (EMPTY=BA and EMP_END=BA), and PE(BA)=FFF and NE(BA)=FFF are recorded in the translation units corresponding to the block simultaneously (s604). If it is determined that it is not the first found non-used block, the translation units corresponding to the non-used block are also updated, that is PE(BA) is set to EMP_END and NE(BA) is set to FFF, and the indicator EMP_END points to the memory block address (BA) (s606). Regardless of whether step s604 or s606 is executed, it is determined whether the block is a last block or not (s605). If it is not the last block, the steps subsequent to step s601 mentioned above are executed on the next bock. If it is the last block, the generation of the non-used memory block series link table is completed (s610).

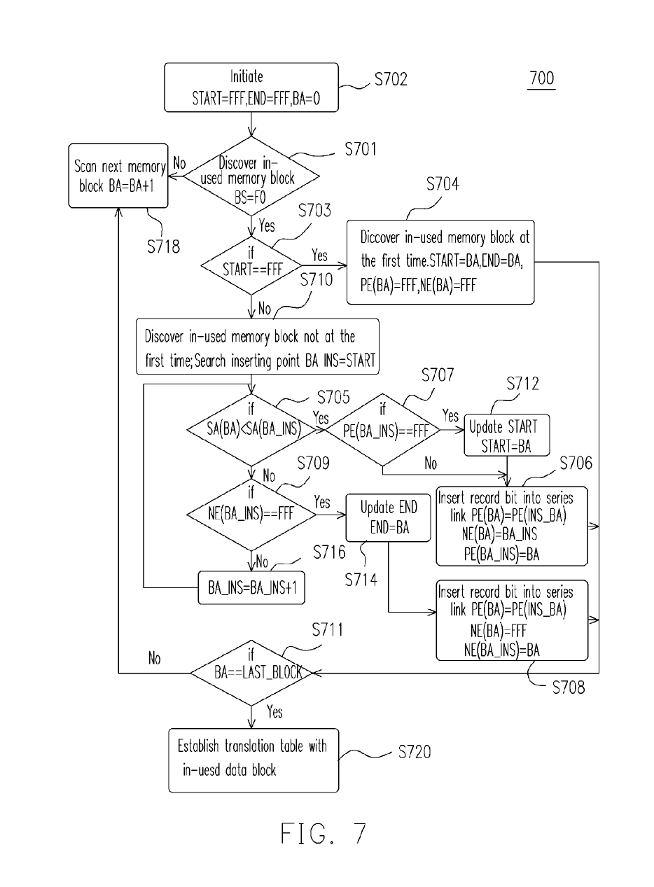

Referring to both FIGS. 4B and 7, which schematically show a process of updating the in-used series link table when the memory block is in-used. Two indicators START and END shown in FIG. 4B are used as the reference indicators for generating the in-used block series link table. Similarly, two indicators START and END are initialized to a default value (e.g. FFF), and the block address (BA) of the memory is set to 0 (s702). A position in the series link data structure where the translation units are inserted into is searched first according to the start address (SA) and the data length (DL) parameters marked by the preceding description unit of the data frame, and both the NE indicator of the previous entry translation unit and the PE indicator of the next entry translation unit are updated. In addition, the block address (BA) of the previous entry translation unit is registered as the NE indicator of the current entry translation unit, and the block address (BA) of the next entry translation unit is registered as the PE indicator of the current entry translation unit. Then, it is determined whether the in-used block BS=F0 is found or not (s701). If it is found, it is then determined whether it is a first found in-used block or not (s703). If it is the first found in-used block, following values are set: START=BA, END=BA, PE(BA)=FFF, and NE(BA)=FFF (s704). If it is not the first found in-used block, it is searching for an insert point. Wherein, a representative insert point indicator BA_INS is set as the translation unit, which are pointed by the START indicator (s710). Before it is inserted, it has to determine whether the SA value of the non first time found in-used block is less than the value pointed by the insert point indicator BA_INS or not. If it is, it is determined whether the previous translation unit of the BA_INS indicator value is the first in-used block or not (s707). It is the first in-used block, the START indicator is updated to the found block address first and then the translation unit is inserted into the series link (s706). If it is not the first in-used block, the translation unit is inserted into the series link directly (s706). If it is determined that the SA value of the found in-used block is greater than or equal to the value pointed by the insert point indicator BA_INS (s705), it is then determined whether the next translation unit of the BA_INS is a last in-used block or not (s709). If it is the last in-used block, the END indicator is updated, and the found in-used block is marked as the last in-used block (s714). Then, the translation unit corresponding to the last in-used block is inserted into the in-used series link (s708). However, when the next translation unit of the BA_INS is not the last in-used block, the determining operation is executed onto the next BA_INS. When the scanning process mentioned above is executed on the last block, the generation of the in-used block series link table is completed.

It should be noted that in an embodiment of the present invention, the translation table uses a bidirectional series link data structure to generate the translation relation between the in-used memory block and the system address. In order to reduce the built-in buffer size of the controller, or in order to improve the performance of searching the corresponding memory block address, other data structure may be applied in the present invention.

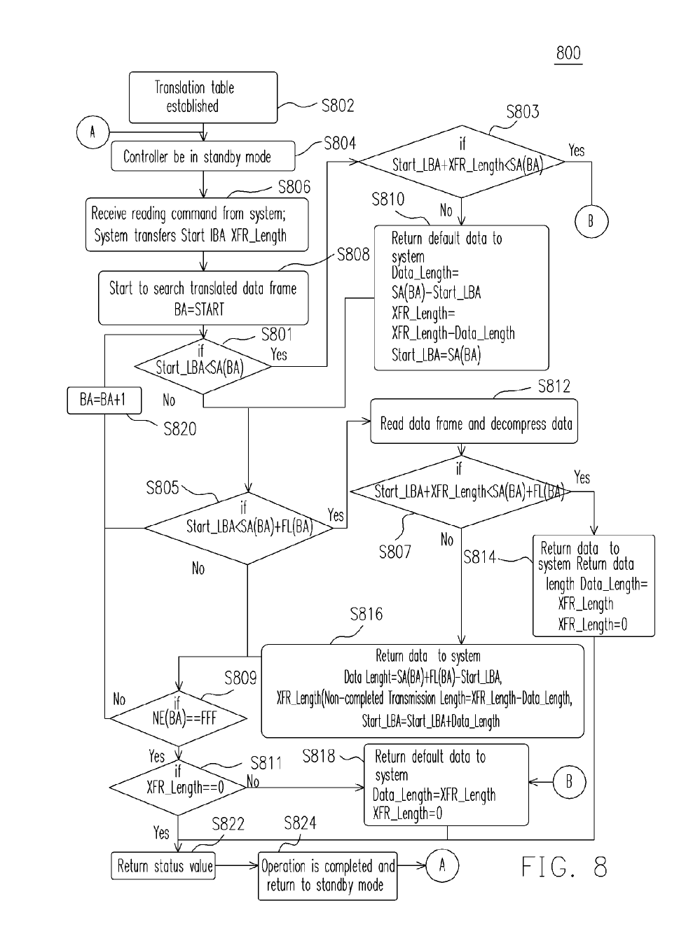

Referring to FIG. 8, after the translation table is generated (s902), the controller is ready to take the access instruction provided by the system (s804). When the system issues the read instruction, both LBA address and data length of the required data are transmitted to the silicon storage media (s806). Meanwhile, the controller of the silicon storage media searches for a corresponding data frame in the translation table starting from the memory block address pointed by the START indicator (s808). Wherein, when the start point and the length of the data to be read are beyond the start point of a most front memory block address (s801 and s803), the process enters into a connection node B and a default value is returned, which indicates the data to be read is not in the memory now. However, when part of data length is over the start point of the most front memory block address (s801 and s803), in such case part of the default value and part of the read data are sent back to the system (s810, s805 and s812). In addition, when the start address of the data to be read and the data block are within the start point of the most front memory block address and the data frame size range (s805 and s807), the data frame is read into the data buffer for decompression (s812). After the data frame is decompressed, the original data is sent back to the system (s816). When the start address of the data to be read is at the start point of the most front memory block address but part of the data to be read is beyond the data frame size range (s805 and s807), in such case part of the data length is sent back to the system, and the start address is updated simultaneously in order to completely transmit all remaining data in next time. For other conditions rather than the one mentioned above, in other words, when the corresponding data frame address is not obtained, a default data format is sent back to the system directly (s818).

Wherein, when the controller is in the process of updating the data frame, the translation table buffer is also updated, and a translation relation is recorded in the preceding description unit. The address mapping module records the address of the original data, and searches the translation table buffer according to the read access instruction provided by the system for obtaining the corresponding memory block, and finally reads the data frame from the corresponding memory block.

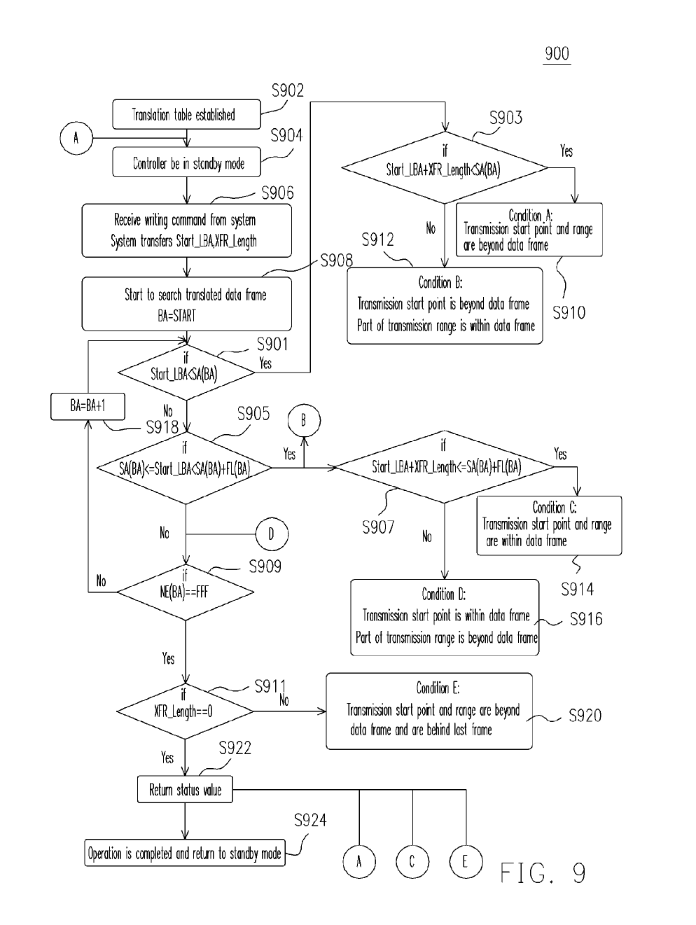

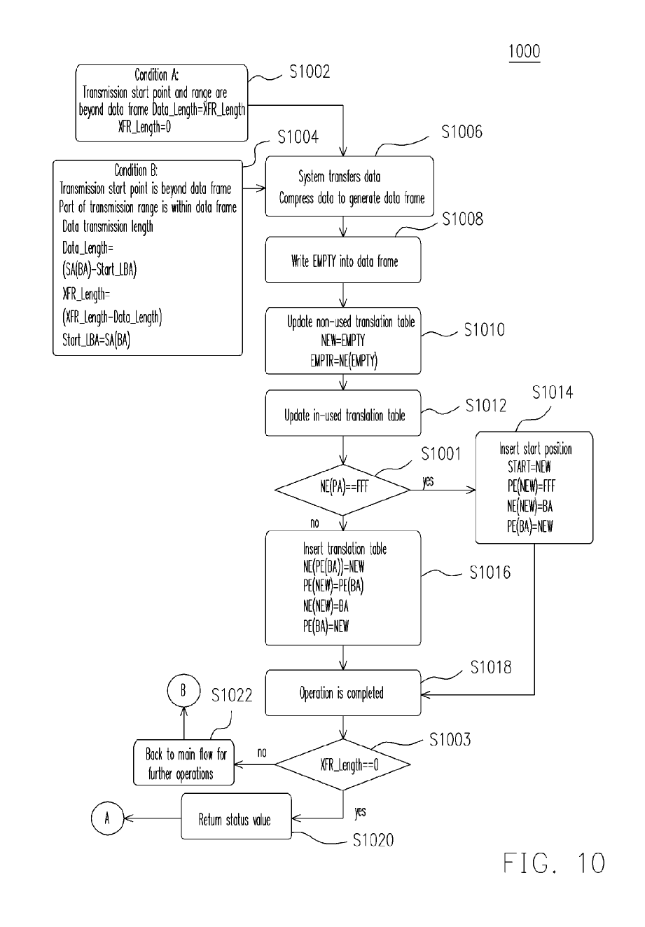

Referring to FIG. 9˜12, wherein FIG. 9 schematically shows a main flow of a write operation, and FIG. 10˜12 schematically show sub flows of the process according to different relationships between the transmission start point/range and the data frame.

Referring to FIG. 9, after the translation table is generated (s902), the controller is ready to take the access instruction provided by the system now (s904). When the system issues the write instruction (s906), the controller immediately searches the translation table to check whether it can obtain the memory block address corresponding to the system read address from the translation table or not (s908). Afterwards, five steps s901, s903, s905, s909, and s911 are executed respectively to determine whether the data to be written is an update data or a new written data. Therefore, there are five different conditions as follows: Condition A (s910), in which both the transmission start point and the data range are beyond the data frame; Condition B (s912), in which the transmission start point is beyond the data frame but the data range is within the data frame; Condition C (s914), in which both the transmission start point and the data range are within the data frame; Condition D (s916), in which the transmission start point is within the data frame but part of the data range is beyond the data frame; and Condition E (s920), where both the transmission start point and the data range are beyond the data frame and also behind the last data frame. These five conditions are described in detail hereinafter.

It should be noted that the processes mentioned above may be achieved via the firmware implementation of the controller. In order to accelerate the data access in system, it is also possible to integrate the hardware circuitry into the address mapping module, such that the controller can rapidly search and determine the relationship between the system access object address and the translation table for further operations.

Five different conditions A, B, C, D, and E as shown in FIG. 10˜12 are described hereinafter.

Condition A: Referring to FIG. 10, in condition A mentioned above, it is known from the result of searching the translation table that both the start point of the system writing object address and the range of the transmission data length are beyond the existing data frame, and the start address is equal to the data length which is marked by the data frame BA. Therefore, a value EMPTY is directly obtained from the non-used memory block translation table, and the new data frame is stored and recorded. If BA is exactly the start address START of the in-used translation table, the new added data frame NEW is inserted into the most front end of the in-used translation table. Otherwise, the new added data frame NEW is inserted in front of the in-used translation table BA and behind PE (BA), and all related indicators are updated.

Condition B: Referring to FIG. 10, in condition B mentioned above, the start point of the system writing object address is beyond the existing data frame and part of the transmission data length range is within the existing data frame. Meanwhile, the process for processing the front section of not within the existing data frame is the same as the one used in Condition A, whereas the rear section is further processed by the main flow.

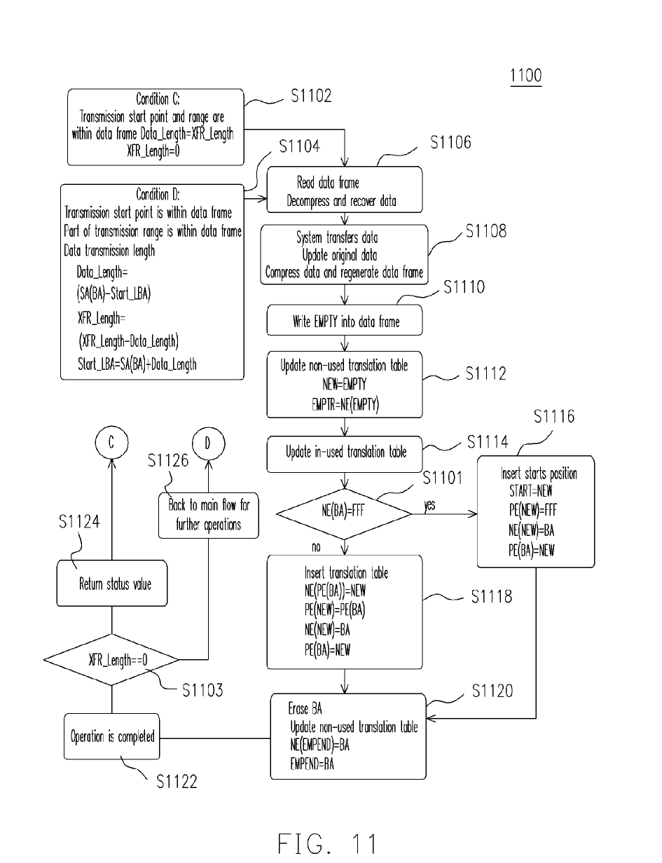

Condition C: Referring to FIG. 11, in condition C mentioned above, it is known from the result of searching the translation table that both the start point of the system writing object address and the range of the transmission data length are within the existing data frame. Therefore, a corresponding memory block BA is directly obtained from the in-used memory block translation table, and the data is read and decompressed. After the original data is updated with the data XFR_Length provided by the system and the data is recompressed, a new data frame is generated. Then, a value of EMPTY is obtained from the non-used memory block translation table, and the updated data frame is stored and recorded in the memory block EMPTY. If BA is exactly the start address START of the in-used translation table, the new updated data frame NEW is inserted into the most front end of the in-used translation table. Otherwise, the new updated data frame NEW is inserted behind the in-used translation table BA and PE (BA), and all related indicators are updated. The BA memory block is erased first and then inserted behind the tail of the non-used memory block translation table.

Condition D: Referring to FIG. 11, in condition D mentioned above, it is known from the result of searching the translation table that the start point of the system writing object address is within the existing data frame but the data transmission range is beyond the original data length of the corresponding data frame. Meanwhile, the process for processing the front section of within the existing data frame is the same as the one used in Condition C, and the rear section of beyond the existing data frame is further processed by the main flow after the transmission start address Start_LBA and the data transmission length XFR_Length are tuned.

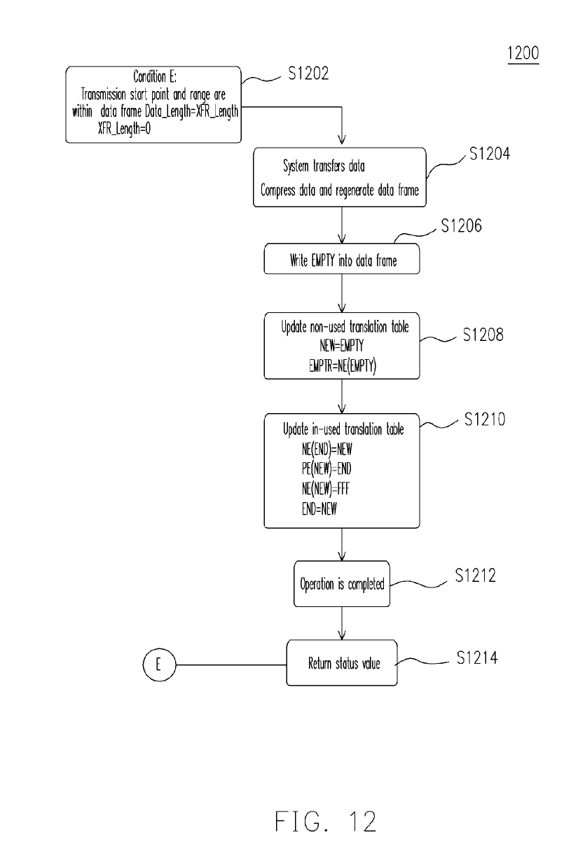

Condition E: Referring to FIG. 12, in condition E mentioned above, it is known from the result of searching the translation table that both the start point of the system writing object address and the range of the data transmission length are beyond the existing data frame, and the start address is over the data length of the last data frame BA (i.e. PE(BA)==FFF). Therefore, a value EMPTY is directly obtained from the non-used memory block translation table, and the original data provided by the system is received for generating the data frame, which is then stored and recorded in the new added data frame NEW. Then, the new added data frame NEW is inserted behind the tail of the in-used memory block translation table, and all related indicators are updated.

Although the invention has been described with reference to a particular embodiment thereof, it will be apparent to one of the ordinary skill in the art that modifications to the described embodiment may be made without departing from the spirit of the invention. Accordingly, the scope of the invention will be defined by the attached claims not by the above detailed description.

1. A method of controlling a silicon storage media, accessing a system to read and write data, comprising a memory and a control unit, wherein said memory comprises a plurality of memory blocks, each of said memory blocks comprises a plurality of data frames those include a preceding description unit, a plurality of compressed sector data, and an error checking code; and said control unit comprises a translation table buffer and an address mapping module; said means comprising:
reading a data frame to access a preceding description unit, and establishing a translation table;
accessing a memory block mirrored by said data frame in accordance with said translation table; and
reading or writing data from/into said memory block.

2. The method as cited in claim 1, wherein said preceding description unit comprises:
a block status (BS);
a start address (SA), indicating the address where said memory block originally stores said data; and
a data length (DL), indicating the length of said data which said memory block stores.

3. The method as cited in claim 1, wherein said preceding description unit further comprises:
an algorithm indicator (Al), indicating a procedure which said control unit choose to compress/decompress said data; and
a parameter indicator (PI), indicating a parameter table which said control unit choose to mirror.

4. The method as cited in claim 1, wherein said method of establishing said translation table further comprises method of establishing translation table with non-used memory block and establishing translation table with in-used memory block, and updating said non-used/in-used translation table in accordance with read/write index.

5. The method as cited in claim 4, when establishing said non-used translation table, further comprising:
scanning memory blocks sequentially;
receiving a non-used memory block (BS=FF);
detecting whether the parameter of said non-used memory block equals to a predetermined value (EMPTY==FFF) or not, if yes, replacing values of said parameter and the last parameter of said non-used memory block with the address of sequential memory block (EMPTY=BA, EMP_END=BA), and replacing values of the previous entry and the next entry of said non-used memory block with said predetermined value (PE(BA)=FFF, NE(BA)=FFF); and
after scanning the last memory block, establishing said non-used translation table according to the record of replacing said values.

6. The method as cited in claim 5, when the parameter of said non-used memory block is not equal to said predetermined value, replacing values of said last parameters of said non-used memory block and its mirrored next entry with said address of sequential memory block (NE(EMP_END)=BA, EMP_END=BA);
replacing values of said previous entry and next entry of said non-used memory block with said last parameter (PE(BA)=EMP_END) and said predetermined value (NE(BA)=FFF); so as to provide said record to establish said non-used translation table.

7. The method as cited in claim 4, when establishing said in-used translation table, further comprising:
scanning memory blocks sequentially;
receiving a in-used memory block (BS=F0);
detecting whether the parameter of said in-used memory block equals to a predetermined value (SRART==FFF) or not, if yes, replacing values of said parameter and the last parameter of said in-used memory block with address of sequential memory block (START=BA, END=BA), and replacing values of the previous entry and the next retry of said in-used memory block with said predetermined value (PE(BA)=FFF, NE(BA)=FFF); and
after scanning the last memory block, establishing said in-used translation table according to the record of replacing said values.

8. The method as cited in claim 7, when the parameter of said in-used memory block is not equal to said predetermined value, further comprising:
receiving the preceding description unit of a data frame which is mirrored by said in-used memory block to derive the address of a inserted point which is mirrored by said in-used memory block (BA_INS=START);
when the start address of said in-used memory block is less than the start address of said inserted point, determining if the parameter of the previous data frame of said inserted point is the predetermined value (PE(BA_INS)==FFF) or not, if yes, replacing the parameter of said in-used memory block with address of sequential memory block (START=BA); if no, replacing said front data frame of said memory block with the same as said inserted point (PE(BA)=PE(INS_BA), replacing said next entry of said memory block with the address of said inserted point (NE(BA)=INS_BA), and replacing previous entry of said inserted point with the address of sequential memory block (PE(BA_INS)=BA);
when said start address of said in-used memory block is not less than said start address of said inserted point, determining if the parameter of next data frame of said inserted point is the predetermined value (NE(BA_INS)==FFF) or not, if no, determining continuously the start address of next inserted point; if yes, replacing the last parameter of said in-used memory block with the address of sequential memory block (END=BA), replacing said front data frame of said memory block with the same as said inserted point (PE(BA)=PE(INS_BA), replacing said next entry of said memory block with the predetermined value (NE(BA)=FFF), and replacing said next entry of said inserted point with the address of sequential memory block (NE(BA_INS)=BA); and
after scanning the last memory block, establishing said in-used translation table according to the record of replacing said values.

9. The method as cited in claim 1, when said system transmits a read instruction, further comprising:
searching an address which is mirrored by said data of said memory block corresponding to said read instruction according to said translation table; and
determining if receiving said mirrored address, if yes, reading data frame of said mirrored address, and decompressing and transmitting original data back to said system; if no, transmitting predetermined data frame to said system.

10. The method as cited in claim 1, when said system transmits a write instruction, further comprising:
searching an address which is mirrored by said data of said memory block corresponding to said write instruction according to said translation table; determining if receiving said mirrored address, if yes, reading data frame of said mirrored address to decompress, and updating said data frame corresponding with the data transmitted from said system; erasing the data in said data frame of said mirrored address, and store the updated data frame into a non-used memory block; and updating said translation table.

11. The method as cited in claim 10, when determining if receiving said mirrored address, if no, constructing a data frame corresponding to the data which said system wants to write, and store into a non-used memory block, and updating said translation table.

12. The method as cited in claim 11, when the start address and the length of said data transmitted by said system are beyond said data frame, said system compressing said data, and updating said in-used translation table and said start address.

13. The method as cited in claim 11, when said start address of said data is beyond said data frame, adjusting and compressing the length of said data, and updating said in-used translation table and said start address.

14. The method as cited in claim 11, when said start address and said length of said data are within said data frame, said system decompressing said data, and re-compressing said decompressed data and said data with respect to said write instruction to form a data frame, and updating said in-used translation table, said start address and non-used translation table.

15. The method as cited in claim 11, when said length of said data is beyond said data frame, adjusting said length and decompressing said data, re-compressing said decompressed data and said data with respect to said write instruction to form a data frame, and updating said in-used translation table, said start address and non-used translation table.

16. The method as cited in claim 11, when said start address and said length of said data are not only beyond but also behind said data frame, said system compressing said data to reform another data frame, and updating said in-used translation table and said non-used translation table.

17. A silicon storage media, reading and writing data with relation to a system, comprising:
a memory, having a plurality of memory blocks, and each memory block having a plurality of data frames; and
a control unit, further comprising:
a system interface, serving a channel of interfacing between said system and said control unit;
a first system data buffer, storing temporality data;
a microprocessor, executing the process of reading, writing, and erasing;
a first memory data buffer, storing temporality data; and
a memory interface, serving a channel of interfacing between said control unit and said plurality of memory.

18. The silicon storage media as cited in claim 17, wherein the control unit further comprises a data compression/decompression module.

19. The silicon storage media as cited in claim 17, wherein the control unit further comprises a second system data buffer and a second memory data buffer for temporarily storing data between said data compression/decompression module and said system interface and said memory interface, respectively.
